(19) United States
(12) Patent Application Publication
(10) Pub. No.: US 2024/0414990 A1
(43) Pub. Date: Dec. 12, 2024

(54) MICROLENS STRUCTURE AND MANUFACTURING METHOD THEREFOR, AND DISPLAY APPARATUS

(71) Applicant: BOE Technology Group Co., Ltd., Beijing (CN)

(72) Inventors: Renquan GU, Beijing (CN); Huili WU, Beijing (CN); Shipei LI, Beijing (CN); Sheng XU, Beijing (CN); Wei HE, Beijing (CN); Lizhen ZHANG, Beijing (CN); Qi YAO, Beijing (CN); Feng ZHANG, Beijing (CN); Kang GUO, Beijing (CN); Guangcai YUAN, Beijing (CN); Xue DONG, Beijing (CN)

(21) Appl. No.: 18/704,044

(22) PCT Filed: Dec. 2, 2021
(86) PCT No.: PCT/CN2021/135156

§ 371 Date: Apr. 23, 2024

(51) Int. Cl. H10K 59/80; G02B 3/00; H10K 59/12

(52) U.S. Cl. CPC H10K 59/879; G02B 3/005; G02B 3/0056; H10K 59/1201

(57) ABSTRACT

Embodiments of the present disclosure provide a microlens structure and a manufacturing method therefor, and a display apparatus. The microlens structure comprises: a base substrate; and a plurality of microlenses, located at one side of the base substrate, wherein the material of each microlenses comprises a product generated after crosslinking a non-photosensitive resin monomer.

### TECHNICAL FIELD

The present disclosure relates to the technical field of 3D display, and in particular to a microlens structure, a manufacturing method therefor, and a display apparatus.

### BACKGROUND

Micro lenses have the function of refracting light and focusing light, and can be applied to various optical components and devices, such as 3D light field display, augmented reality (AR), virtual reality (VR), sensors, optical functional films and etc.

### SUMMARY

A microlens structure provided by an embodiment of the present disclosure includes:
a base substrate;
a plurality of micro lenses located on one side of the base substrate; wherein a material of the micro lenses includes a product of cross-linked non-photosensitive resin monomer.

Optionally, in the microlens structure provided by the embodiment of the present disclosure, in 400 nm-600 nm band, a transmittance of non-photosensitive resin is greater than or equal to 50%.

Optionally, in the microlens structure provided by the embodiment of the present disclosure, the material of the micro lenses does not include a photosensitive group.

Optionally, in the microlens structure provided by the embodiment of the present disclosure, the product of cross-linked non-photosensitive resin monomer includes at least one of polyacrylic resin, polyimide resin or phenolic resin.

Optionally, in the microlens structure provided by the embodiment of the present disclosure, a surface figure accuracy of the micro lenses is less than 10 nm, and a roughness of the micro lenses is less than 1 nm.

Optionally, the microlens structure provided by the embodiment of the present disclosure further includes a light-shielding layer between the base substrate and the micro lenses, wherein the light-shielding layer includes a plurality of sub-shielding parts arranged at intervals, and each of the sub-shielding parts is located in a gap between adjacent micro lenses.

Optionally, in the microlens structure provided by the embodiment of the present disclosure, the micro lenses cover edges of the sub-shielding parts.

Correspondingly, an embodiment of the present disclosure further provides a display apparatus, including: a display panel, and the microlens structure according to any one of aforementioned embodiments located on a light-emitting side of the display panel.

Optionally, in the display apparatus provided by the embodiment of the present disclosure, the base substrate of the microlens structure is an interlayer, and the display apparatus further includes a planarization layer on a side of the micro lenses away from the base substrate, and a refractive index of the planarization layer is smaller than a refractive index of the micro lenses.

Optionally, in the display apparatus provided by the embodiment of the present disclosure, an alignment deviation between the microlens structure and the display panel is less than or equal to 5 μm.

Optionally, in the display apparatus provided by the embodiment of the present disclosure, the display panel includes: a driving back panel, and a plurality of sub-pixels between the driving back panel and the base substrate; the plurality of sub-pixels are divided into a plurality of pixel islands, each of the pixel islands includes a plurality of sub-pixels, and sub-pixels in a same pixel island display a same color; wherein
along a direction perpendicular to an extension direction of one of the micro lenses, one of the pixel islands corresponds to at least one of the micro lenses, and a quantity of sub-pixels included in each of the pixel islands is greater than or equal to a quantity of the micro lenses corresponding to the each of the pixel islands.

Optionally, in the display apparatus provided by the embodiment of the present disclosure, the display panel includes a display area and a peripheral area disposed around the display area, the peripheral area includes: a first sub-area and a second sub-area along a direction perpendicular to an extension direction of one of the micro lenses, and a third sub-area and a fourth sub-area along the extension direction of one of the micro lenses; wherein
along the direction perpendicular to the extension direction of one of the micro lenses, a quantity of the micro lenses arranged in the first sub-area and the second sub-area is greater than or equal to 5, respectively.

Correspondingly, an embodiment of the present disclosure further provides a method for manufacturing the microlens structure according to any one of aforementioned embodiments, including:
fabricating the plurality of micro lenses on the base substrate; wherein a material of the micro lenses is a product of cross-linked non-photosensitive resin.

Optionally, in the method provided by the embodiment of the present disclosure, the fabricating the plurality of micro lenses on the base substrate, includes:
forming a non-photosensitive resin layer on the base substrate;
coating a photoresist layer on a side of the non-photosensitive resin layer away from the base substrate;
exposing and developing the photoresist layer to form a photoresist pattern;
etching the non-photosensitive resin layer by using the photoresist pattern as a mask, to form a non-photosensitive resin pattern;
removing the photoresist pattern; and
performing a thermal reflow process on the non-photosensitive resin pattern to form the plurality of micro lenses.

Optionally, in the method provided by the embodiment of the present disclosure, after the forming the non-photosensitive resin layer on the base substrate, and before the coating the photoresist layer on the side of the non-photosensitive resin layer away from the base substrate, the method further includes:
forming a passivation layer on a side of the non-photosensitive resin layer away from the base substrate.

Optionally, in the method provided by the embodiment of the present disclosure, after the forming the photoresist pattern and before the etching the non-photosensitive resin layer by using the photoresist pattern as a mask, the method further includes:
etching the passivation layer by using the photoresist pattern as a mask, to form a passivation layer pattern.

Optionally, in the method provided by the embodiment of the present disclosure, the etching the non-photosensitive resin layer by using the photoresist pattern as a mask, to form the non-photosensitive resin pattern, includes:
etching the non-photosensitive resin layer by using the photoresist pattern and the passivation layer pattern as a mask, to form the non-photosensitive resin pattern.

Optionally, in the method provided by the embodiment of the present disclosure, after forming the non-photosensitive resin pattern and before performing the thermal reflow process on the non-photosensitive resin pattern, the method further includes:
concurrently removing the passivation layer pattern and the photoresist pattern.

Optionally, in the method provided by the embodiment of the present disclosure, before the fabricating the plurality of micro lenses on the base substrate, the method further includes:
forming a light-shielding layer on the base substrate; wherein the light-shielding layer includes a plurality of sub-shielding parts arranged at intervals, and each of the sub-shielding parts is located in a gap between adjacent micro lenses.

### BRIEF DESCRIPTION OF FIGURES

In order to more clearly illustrate the technical solutions in the embodiments of the present disclosure, the drawings that need to be used in the description of the embodiments will be briefly introduced below. Obviously, the drawings in the following description are only some embodiments of the present disclosure. Those of ordinary skill in the art can also obtain other drawings based on these drawings without making creative efforts.

FIG. 1 is a schematic diagram of the reaction principle of photosensitive resin provided in the related art under thermal initiation.

FIG. 2 is a schematic diagram of a transmittance of the photosensitive resin provided in the related art.

FIG. 3A is a schematic diagram of a microlens structure provided by an embodiment of the present disclosure.

FIG. 3B is a scanning electron micrograph of micro lenses and sub-shading parts in FIG. 3A.

FIG. 4 is a schematic diagram of the comparison of the transmittance between the non-photosensitive resin provided by the embodiment of the present disclosure and the photosensitive resin in the related art.

FIG. 5A is a top view of micro lenses in FIG. 3A.

FIG. 5B is another top view of micro lenses in FIG. 3A.

FIG. 6 is a flowchart of a method for manufacturing a microlens structure provided by an embodiment of the present disclosure.

FIGS. 7A to 7G are structural schematic diagrams of the microlens structure provided by the embodiments of the present disclosure after each manufacturing step.

FIG. 8A to 8F are structural schematic diagrams of the microlens structure provided by the embodiments of the present disclosure after each manufacturing step.

FIG. 9 is a structural schematic diagram of a display apparatus provided by an embodiment of the present disclosure.

FIG. 10A is a top view of the display apparatus shown in FIG. 9.

FIG. 10B is a schematic diagram of a specific structure of the display apparatus shown in FIG. 9.

FIG. 11 is a three-dimensional schematic diagram of a microlens structure and a display panel in FIG. 9.

FIG. 12 is another top view of the display apparatus.

### DETAILED DESCRIPTION

In order to make the purpose, technical solutions and advantages of the embodiments of the present disclosure clearer, the technical solutions of the embodiments of the present disclosure will be clearly and completely described below in conjunction with the accompanying drawings of the embodiments of the present disclosure. Apparently, the described embodiments are some of the embodiments of the present disclosure, not all of them. And in the case of no conflict, the embodiments in the present disclosure and the features in the embodiments can be combined with each other. Based on the described embodiments of the present disclosure, all other embodiments obtained by persons of ordinary skill in the art without creative effort fall within the protection scope of the present disclosure.

Unless otherwise defined, the technical terms or scientific terms used in the present disclosure shall have the usual meanings understood by those skilled in the art to which the present disclosure belongs. “First”, “second” and similar words used in the present disclosure do not indicate any order, quantity or importance, but are only used to distinguish different components. “Comprising” or “including” and similar words mean that the elements or items appearing before the word include the elements or items listed after the word and their equivalents, without excluding other elements or items. Words such as “connect” or “link” are not limited to physical or mechanical connections, but may include electrical connections, whether direct or indirect.

It should be noted that the size and shape of each figure in the drawings do not reflect the true scale, but are only intended to illustrate the present disclosure. And the same or similar reference numerals represent the same or similar elements or elements having the same or similar functions throughout.

With the continuous development of display technology, the market and users have higher and higher requirements for the look and feel of display technology, and 3D display technology has gradually entered people's field of vision. At present, the implementation methods of 3D display technology include glasses type, light shielding type, light refraction type, etc., and the photorefractive 3D display can not only realize the naked eye 3D display, but also avoid the loss of brightness of the display apparatus, so the photorefractive 3D display is important research directions for 3D display technology development.

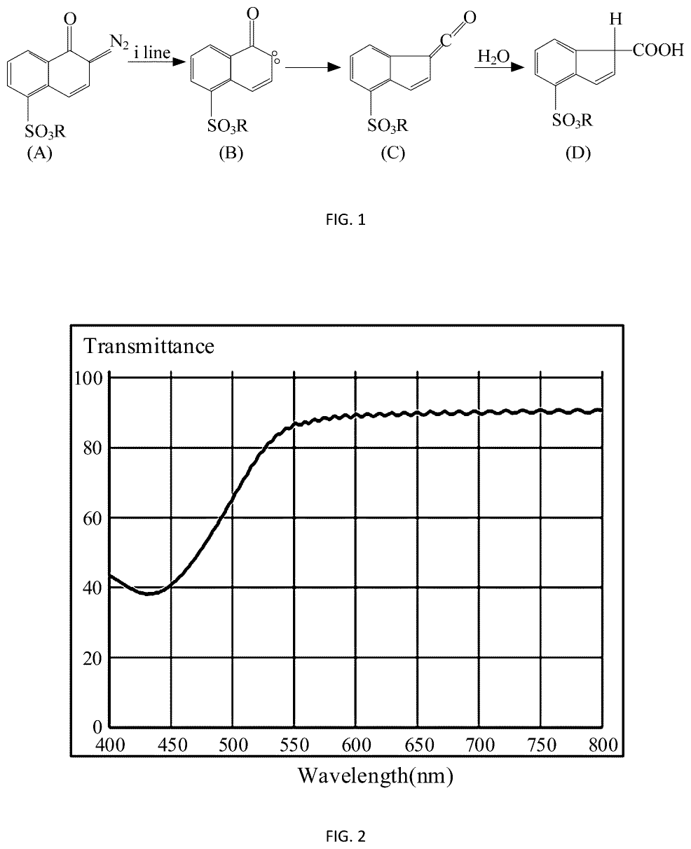

At present, the photorefractive 3D display mainly uses a combination of pixel islands and micro lenses to achieve the effect of 3D light field display. However, the processing technology of micro lenses modules is extremely difficult. The common methods for preparing micro lenses include injection molding and nanoimprinting, and then the prepared micro lenses are bonded with light-emitting devices to form a 3D display apparatus. However, the injection molding, nanoimprinting and the likes are difficult to process, high in cost, and low in alignment accuracy, so a thermal reflow process is currently a mainstream solution for preparing micro lenses. In the related art, the solution of using the thermal reflow process to make micro lenses is to use photosensitive resin to form patterned micro-lenses regions under photolithography, and then heat the reflow to form microlens structures. Generally, the photosensitive resin contains photosensitive groups, the most common such as diazonaphthoquinone (DNQ), as shown in (A) in FIG. 1. (A) in FIG. 1 is the structure of diazonaphthoquinone sulfonate. The diazonaphthoquinone sulfonate is a commonly used photosensitive resin, and has azidoquinone groups, and each azidoquinone group has a lone pair of electrons of nitrogen atoms. Since the photosensitive resin itself is at the i-line (365 nm) photosensitive, so the photosensitive resin is exposed to the i-line. The structure of (A) in FIG. 1 becomes the structure shown in (B) in FIG. 1, and becomes the structure shown in (C) in FIG. 1 after wolff rearrangement, then meets water to form carboxylic acid groups, as shown in (D) in FIG. 1. The electron cloud inside the molecule is in a large conjugated system, the structure tends to be stable, and the absorption spectrum is blue-shifted, so the photosensitive resin has low transmittance in the blue light region. Since the photosensitive groups still remain in the resin after the microlens structure is prepared, the micro lenses made of the photosensitive resin are prone to yellowing. As shown in FIG. 2, FIG. 2 is a result of testing on the transmittance of the photosensitive resin in the visible light band by the inventor of the present disclosure. It can be seen that the transmittance of the photosensitive resin in the blue light region is low, so the micro lenses made of photosensitive resin is prone to yellowing. In the related art, in order to increase the transmittance of the photosensitive resin, a photobleaching process is generally required after development, but the improvement of the transmittance through the photobleaching process is also limited.

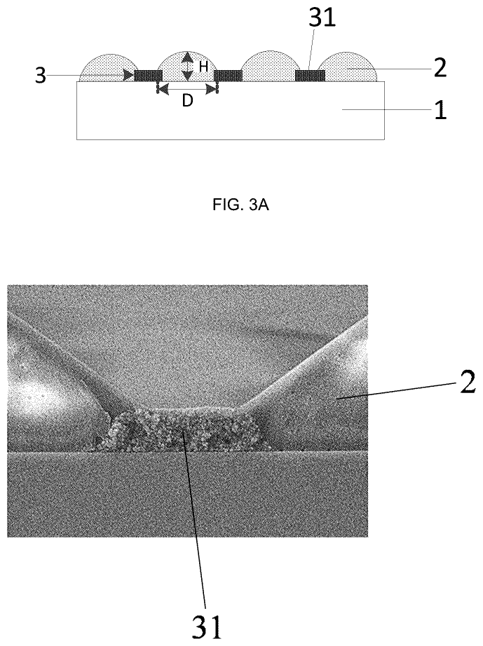

In view of this, in order to solve the problem of yellowing in the related art due to the micro lenses made of photosensitive resin with low transmittance, an embodiment of the present disclosure provides a microlens structure, as shown in FIG. 3A, including:
a base substrate 1; and
a plurality of micro lenses 2 located on one side of the base substrate 1; where the material of the micro lenses 2 includes a product of cross-linked non-photosensitive resin monomer.

Here, the non-photosensitive resin monomer can be understood as: no photosensitive group is attached to the resin monomer, or the photosensitive resin monomer is not mixed with a photosensitizer. The photosensitizer may include photosensitive groups. The non-photosensitive resin monomers or prepolymers of non-photosensitive resin monomers cannot be patterned by direct photolithography.

Specifically, the material of the micro lenses 2 may include a product of thermal initiation cross-linked resin, and the material of the micro lenses provided in the embodiments of the present disclosure does not have photosensitive groups.

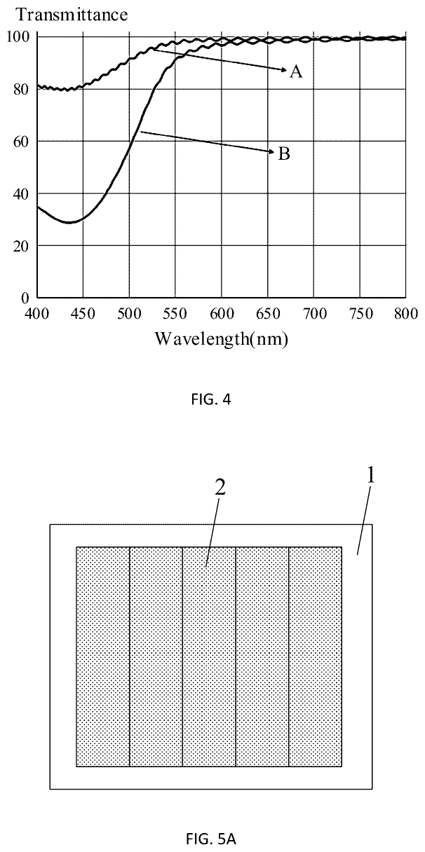

After the non-photosensitive resin monomer is thermal initiation to form cross-linked resin (hereinafter referred to as “non-photosensitive resin”), the transmittance is greatly improved. As shown in FIG. 4, FIG. 4 is a schematic diagram of the comparison of the transmittance between the non-photosensitive resin and the photosensitive resin (the product of cross-linked resin monomer). The curve A is the transmittance of the non-photosensitive resin in the visible light band, and the curve B is the transmittance of the photosensitive resin in the visible light band. It can be seen that at 400 nm˜550 nm band, the transmittance of non-photosensitive resins is significantly greater than that of photosensitive resins, especially in the blue light region, where the transmittance of photosensitive resins is even lower. Correspondingly, the photosensitive resin monomer can be understood as: the resin monomer connected with the photosensitive groups, or the photosensitive resin monomer mixed with a photosensitizer. Here, the photosensitizer may include photosensitive groups. It should be noted that under light conditions (such as ultraviolet light irradiation), the photosensitive resin monomer or the prepolymer of the photosensitive resin (that is, the product after the prepolymerization of the photosensitive resin monomer) may produce a chemical reaction, the solubility of the photosensitive resin monomer or the prepolymer of the photosensitive resin in the developing solution (e.g. alkaline solution) is increased, so it is easy to be washed off, so it can be patterned by direct photolithography.

Therefore, in the above-mentioned microlens structure provided by the embodiments of the present disclosure, by using non-photosensitive resin to form the microlens structure through thermal initiation, the transmittance of the micro lenses can be greatly improved, and the yellowing problem occurrence of micro lenses made of photosensitive resin in the related art can be avoided.

It should be noted that the above-mentioned thermal initiation may be a heating process in a thermal reflow process. Specifically, the process of manufacturing the microlens structure in the embodiments of the present disclosure can be mainly divided into four steps: 1, forming a whole layer of photoresist on a side of the non-photosensitive resin layer (the film layer with the prepolymer of the non-photosensitive resin) away from the base substrate, exposing the photoresist under the cover of the mask, where the exposure pattern can be but not limited to a rectangle; 2, developing the photoresist after exposure to form a photoresist pattern; 3, etching the non-photosensitive resin to form a microlens pattern with the photoresist pattern as a mask, and; 4, placing the structure formed with the microlens pattern on a heating platform, and forming the microlens structure through a thermal reflow process.

In specific implementation, in the microlens structure provided by the embodiments of the present disclosure, as shown in FIG. 4, the transmittance (A) of the non-photosensitive resin is greater than or equal to 50% in the 400 nm˜600 nm band. Specifically, in the 400 nm˜600 nm band, the transmittance (A) of the non-photosensitive resin is greater than or equal to 75%. When the microlens structure provided by the embodiment of the present disclosure is applied to 3D light field display, it can improve the overall white balance of the display device. More specifically, in the visible light band (400 nm˜780 nm), the transmittance (A) of the non-photosensitive resin is greater than 75%. By using non-photosensitive resin with high transmittance, when the microlens structure provided by the embodiment of the present disclosure is applied to 3D light field display, the micro lenses made of non-photosensitive resin with high transmittance does not affect the luminous color coordinates of the display apparatus, which can reduce the yellowing problem of the microlens structure, thereby improving the overall white balance of the display device.

It should be noted that in the related art, when micro lenses made of photosensitive resin are formed by thermal reflow process, the heating temperature of thermal reflow process is generally higher than 200° C. When the microlens structure is applied to 3D light field display, since the microlens structure is produced directly on the light-emitting side of the display device, and the high-temperature process seriously affects the luminous efficiency and reliability of the display device. For the microlens structure provided by the embodiments of the present disclosure, the heating temperature in the thermal reflow process is only required to be less than 150° C. When the microlens structure is used in conjunction with the display panel (such as OLED display panel, QLED display panel), the high heating temperature may affect the luminous efficiency and reliability of the display devices in the display panel, so using the non-photosensitive resin to make the microlens structure can improve the display effect and reliability of the display panel.

The photosensitive groups may include, but are not limited to azidoquinone groups, benzophenone groups, sulfonic acid groups, or alkenyl ether groups. Therefore, the non-photosensitive resin provided by the embodiments of the present disclosure does not have photosensitive groups such as azidoquinone groups, benzophenone groups, sulfonic acid groups or alkenyl ether groups, and can form a resin after thermal initiation. The cross-linked mesh resin has high transmittance, so the transmittance of the microlens structure is relatively high, and there will be no yellowing problem when the microlens structure is applied to 3D light field display.

In specific implementation, in the above-mentioned microlens structure provided by the embodiments of the present disclosure, the products of non-photosensitive resin monomers that are thermal initiation to cross-link may include, but are not limited to at least one of polyacrylic resins, polyimide resins, or phenolic resins. Specifically, the cross-linked product can be a mesh structure presenting a cross-linked state.

In specific implementation, in the above-mentioned microlens structure provided by the embodiments of the present disclosure, the surface figure accuracy PV of the micro lenses formed by using the thermal reflow process is less than or equal to 10 nm. Further, the surface figure accuracies PV of the micro lenses formed by the thermal reflow process are all less than or equal to 5 nm. The roughness Ra of the micro lenses formed by the thermal reflow process is all less than or equal to 1 nm. Further, the roughness Ra of the micro lenses formed by the thermal reflow process is less than or equal to 0.5 nm. Specifically, it can be measured by an atomic force microscope that the surface figure accuracy PV of the micro lenses is in the range of 1 nm˜10 nm, and the roughness Ra of the micro lenses is in the range of 0.1 nm˜1.0 nm, which is consistent with the application standard of the microlens structure in light field display devices. In comparison, in general, the roughness Ra of micro lenses formed by etching is greater than 10 nm, and the surface figure accuracy PV of micro lenses formed by etching is greater than 10 nm; the roughness Ra of micro lenses formed by nanoimprinting is greater than 1 nm, and the surface figure accuracy PV of micro lenses formed by nanoimprinting is greater than 10 nm. Therefore, a microlens structure with good performance can be formed by using the non-photosensitive resin provided by the embodiments of the present disclosure through a thermal reflow process.

In specific implementation, in the microlens structure provided by the embodiments of the present disclosure, as shown in FIG. 3A, the gap between adjacent micro lenses 2 is in the range of 0 μm˜2.5 μm.

In specific implementation, when the microlens structure is combined with the display device to realize 3D light field display, since there is a certain gap between adjacent micro lenses, in order to prevent the light emitted by the display device from directly exiting through the gap between adjacent micro lenses, thereby causing the problem of light crosstalk, the above-mentioned microlens structure provided by the embodiments of the present disclosure, as shown in FIG. 3A, further includes a light-shielding layer 3 between the base substrate 1 and the micro lenses 2. The light-shielding layer 3 includes a plurality of sub-shielding parts 31 arranged at intervals, and each sub-shielding part 31 is located in the gap between adjacent micro lenses 2. Each sub-shielding part 31 can prevent the problem of light crosstalk. Specifically, as shown in FIG. 3B which is a scanning electron microscope (SEM) photo of the micro lenses 2 and the sub-shielding parts in FIG. 3A. It can be seen that sub-shielding parts 31 are arranged between adjacent micro lenses 2.

Specifically, as shown in FIG. 3A, the width of each sub-shielding part 31 may be in the range of 2 μm˜4.5 μm.

During specific implementation, in the microlens structure provided by the embodiments of the present disclosure, as shown in FIG. 3A, the micro lens 2 covers the edge of the sub-shielding part 31. In this way, the light-shielding layer 3 can be fabricated on the base substrate 1 first, and then a plurality of micro lenses 2 can be formed on the side of the light-shielding layer 3 facing away from the base substrate 1, so that the sub-shielding parts 31 can completely fill the gaps between the micro lenses 2, completely blocking the problem of light crosstalk.

In specific implementation, when the microlens structure is combined with the display device to realize 3D light field display, in order to improve the 3D display effect, reduce light crosstalk, and reduce dizziness caused by binocular radiation, in the microlens structure provided in the embodiments of the present disclosure, as shown in FIG. 3A, the diameter D of the micro lenses 2 can be in the range of 5 μm to 300 μm, and the arc height H of the micro lenses 2 can be in the range of 2 μm to 30 μm.

In specific implementation, the embodiments of the present disclosure do not specifically limit the shape and size of the micro lenses. For example, the micro lenses has a converging effect on light, as shown in FIG. 5A, which is a top view of the micro lenses 2 in FIG. 3A. FIG. 5A takes the micro lenses as a cylindrical lens of an example. As shown in FIG. 5B, FIG. 5B is another top view of the micro lenses 2 in FIG. 3A, and FIG. 5B takes the micro lenses as a circular lens of an example. Of course, the top view of the micro lenses may also be in other shapes (such as ellipse or rounded rectangle, etc.).

Based on the same inventive concept, an embodiment of the present disclosure further provides a method for manufacturing the above-mentioned microlens structure, including:
fabricating the plurality of micro lenses on the base substrate. The material of the micro lenses is a product of thermal initiation cross-linked non-photosensitive resin.

The manufacturing method of the microlens structure provided by the embodiment of the present disclosure can greatly improve the transmittance of the micro lenses by using non-photosensitive resin to form the microlens structure through thermal initiation, and avoid yellowing of the micro lenses made of photosensitive resin in the related art.

The method for manufacturing the microlens structure shown in FIG. 3A provided by the embodiment of the present disclosure is described in detail below.

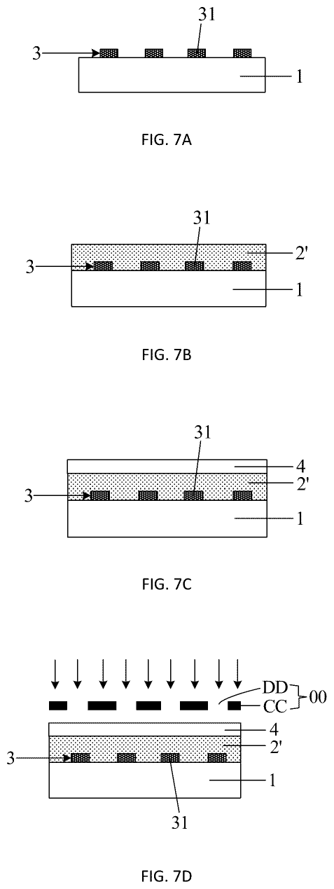

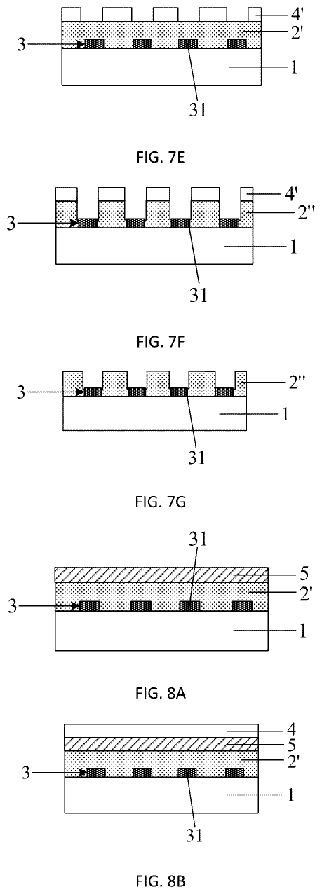

First, a light-shielding material layer is coated on the base substrate 1. The light-shielding material may be a black matrix (BM). The light-shielding material layer is exposed, developed and etched to form a light-shielding layer 3 including a plurality of sub-shielding parts 31, as shown in FIG. 7A.

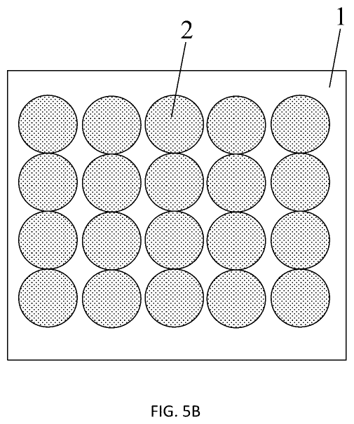

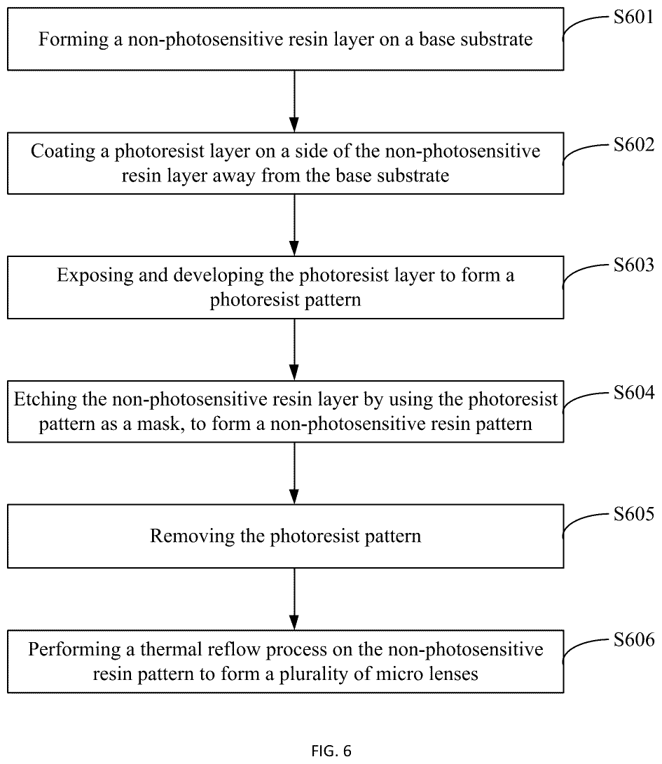

In specific implementation, in the above-mentioned manufacturing method provided by the embodiment of the present disclosure, the fabricating of the plurality of micro lenses on the base substrate, as shown in FIG. 6, may specifically include:
S601. Forming a non-photosensitive resin layer on the base substrate.

Specifically, as shown in FIG. 7B, a non-photosensitive resin layer 2′ is formed on the base substrate 1 on which the light-shielding layer 3 is formed. Specifically, the non-photosensitive resin layer in this step includes a prepolymer of the non-photosensitive resin, and the prepolymer of the non-photosensitive resin is a prepolymerized product of the non-photosensitive resin monomer.

S602. Coating a photoresist layer on a side of the non-photosensitive resin layer away from the base substrate.

Specifically, as shown in FIG. 7C, a photoresist layer 4 is coated on a side of the non-photosensitive resin layer 2′ away from the base substrate 1, and the photoresist of the photoresist layer 4 is a positive photoresist as an example.

S603. Exposing and developing the photoresist layer to form a photoresist pattern.

In a specific embodiment, as shown in FIG. 7D, the photoresist layer 4 is exposed (shown by the arrow) using a mask 00 including light-shielding regions CC and light-transmitting regions DD, wherein the light-transmitting regions DD correspond to the sub-shielding parts 31, and the light-shielding regions CC correspond to gaps between adjacent sub-shielding parts 31. As shown in FIG. 7E, the exposed photoresist layer 4 is developed, so that the photoresist corresponding to the light-transmitting regions DD is developed off, the photoresist corresponding to the light-shielding regions CC remains, thereby forming a photoresist pattern 4′.

S604. Etching the non-photosensitive resin layer by using the photoresist pattern as a mask, to form a non-photosensitive resin pattern.

Specifically, as shown in FIG. 7F, the non-photosensitive resin layer 2′ is etched using the photoresist pattern 4′ as a mask to form a non-photosensitive resin pattern 2″.

S605. Removing the photoresist pattern.

Specifically, as shown in FIG. 7G, the photoresist pattern 4′ is removed.

S606. Performing a thermal reflow process on the non-photosensitive resin pattern to form a plurality of micro lenses.

Specifically, as shown in FIG. 3A, a thermal reflow process is performed on the non-photosensitive resin pattern 2″ to form a plurality of micro lenses 2. Here, each sub-shielding parts 31 is located in the gap between adjacent micro lenses 2.

Specifically, in the thermal reflow process, the prepolymer of the non-photosensitive resin undergoes a thermal initiation cross-linking reaction to form a cross-linked product.

Therefore, the microlens structure shown in FIG. 3A of the present disclosure can be fabricated through the fabrication steps of FIG. 7A to FIG. 7G. Specifically, for the relevant content of the microlens structure, reference may be made to the aforementioned embodiments of the microlens structure, and details are not repeated here.

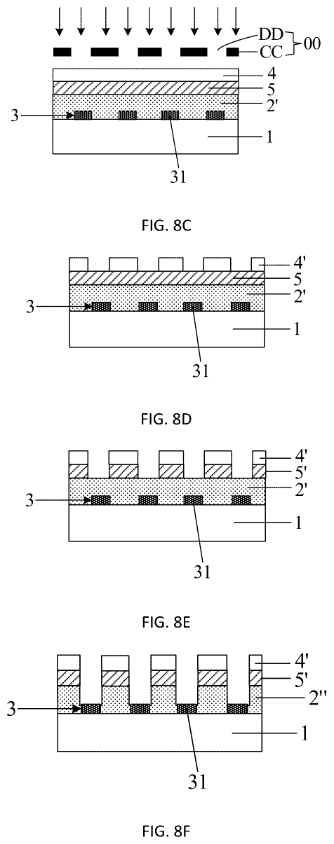

In specific implementation, in order to prevent the photoresist from remaining on the non-photosensitive resin pattern 2″ when removing the photoresist pattern in the above S605, the above manufacturing method provided by the embodiment of the present disclosure, after S601, and before S602, may further include: forming a passivation layer 5 on the side of the non-photosensitive resin layer 2′ away from the base substrate 1, as shown in FIG. 8A. In this way, the structure shown in FIG. 7C accordingly becomes the structure shown in FIG. 8B, the structure shown in FIG. 7D correspondingly becomes the structure shown in FIG. 8C, and the structure shown in FIG. 7E correspondingly becomes the structure shown in FIG. 8D.

In actual implementation, since the passivation layer 5 is formed on the side of the non-photosensitive resin layer 2′ facing away from the base substrate 1 after S601 and before S602, the above manufacturing method provided by the embodiment of the present disclosure after S603, and before S604 using the photoresist pattern as a mask to etch the non-photosensitive resin layer, may further include: etching the passivation layer 5 by using the photoresist pattern 4′ as a mask to form a passivation layer pattern 5′, as shown in FIG. 8E.

In specific implementation, since the passivation layer pattern 5′ is formed after S603 and before S604 using the photoresist pattern as a mask to etch the non-photosensitive resin layer, in the above-mentioned manufacturing method provided by the embodiment of the present disclosure, the above-mentioned S604 can specifically include: etching the non-photosensitive resin layer 2′ by using the photoresist pattern 4′ and the passivation layer pattern 5′ as a mask at the same time, to form the non-photosensitive resin pattern 2″, as shown in FIG. 8F.

In specific implementation, in the above manufacturing method provided by the embodiment of the present disclosure, when removing the photoresist pattern in S605, the passivation layer pattern 5′ and the photoresist pattern 4′ as shown in FIG. 8F are peeled off at the same time, as shown in FIG. 7G.

Therefore, the microlens structure shown in FIG. 3A of the present disclosure can be manufactured through FIG. 7A, FIG. 7B, FIGS. 8A-8F and FIG. 7G. In comparison to the FIG. 7A˜FIG. 7G, the manufacturing steps shown in FIG. 7A, FIG. 7B, FIGS. 8A-8F and FIG. 7G can avoid the problem of photoresist remaining on the non-photosensitive resin pattern 2″ when removing the photoresist.

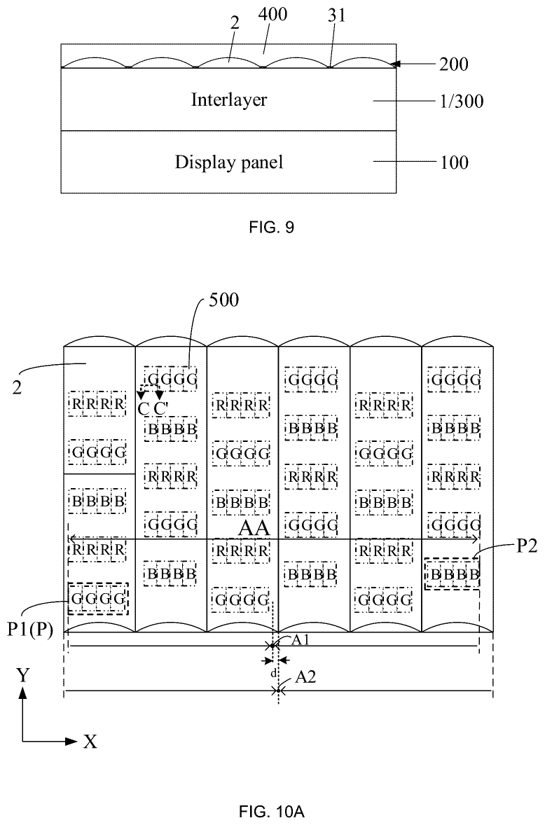

Based on the same inventive concept, an embodiment of the present disclosure further provides a display apparatus, as shown in FIG. 9, including: a display panel 100, and the above-mentioned microlens structure 200 provided by the embodiment of the present disclosure located on a light-emitting side of the display panel 100.

Specifically, the display panel 100 may be an organic light-emitting diode (OLED) display panel. By applying the microlens structure on the light-emitting side of the display panel 100 and refracting the light emitted by the display panel 100 through the microlens structure 200, people can see objects with different depths of field, which is the feeling of seeing the real world, i.e., 3D light field display effect.

In specific implementation, in the above-mentioned display apparatus provided by the embodiment of the present disclosure, as shown in FIG. 9, the base substrate 1 of the microlens structure may be an interlayer 300. The display apparatus further includes a planarization layer 400 on a side of the micro lenses 2 away from the base substrate 1. The refractive index of the planarization layer 400 is smaller than that of the micro lenses 2. Specifically, the micro lenses 2 with high refractive index and the planarization layer 400 with low refractive index form a convex lens structure, which can increase the light extraction effect of the micro lenses 2.

Specifically, the micro lens 2 is a cylindrical lens.

Specifically, when the microlens structure is applied to 3D light field display, the refractive index of the general microlens structure is designed to be greater than or equal to the refractive index of the light-emitting device in the display panel and an interlayer between the micro-lens structure and the light-emitting device, which can ensure that almost all the light emitted by the light-emitting device is emitted, to improve luminous efficiency. The refractive index of the photosensitive resin used in the related art is greater than the refractive index of the interlayer, while the refractive index of the non-photosensitive resin used in the present disclosure is generally higher than that of the photosensitive resin. Therefore, in the present disclosure, the non-photosensitive resin with high refractive index is used to make the microlens structure, which can further ensure that the refractive index of the micro lenses is higher than that of the interlayer, so that the thickness of the interlayer can also be reduced. Therefore, the microlens structure provided by the embodiments of the present disclosure can solve the problems of high temperature, low transmittance and low refractive index when making micro lenses in the existing thermal reflow process.

Specifically, the material of the interlayer 300 may be at least one of organic transparent materials or inorganic transparent materials, for example, including glass.

Specifically, the material of the planarization layer 400 may be resin. Here, when the selected non-photosensitive resin is used to make the micro lenses, the refractive index of the non-photosensitive resin should be greater than the refractive index of the selected resin for the planarization layer.

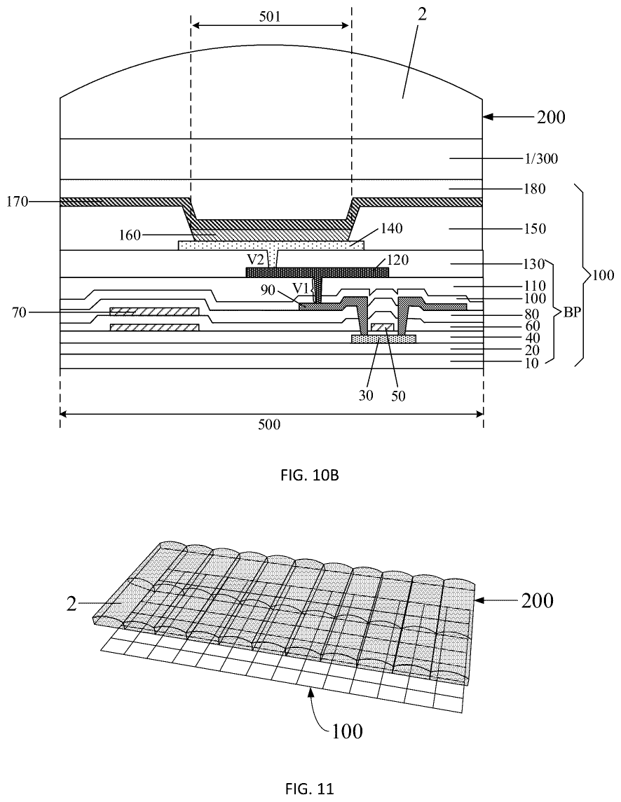

In specific implementation, in the above-mentioned display apparatus provided by the embodiment of the present disclosure, as shown in FIG. 10A, FIG. 10B and FIG. 11, FIG. 10A is a top view of the display apparatus, FIG. 10B is a cross-section view along the CC′ direction in FIG. 10A, FIG. 11 is a three-dimensional schematic diagram of the microlens structure 200 and the display panel 100 in FIG. 10B. The display panel 100 includes: a driving back panel BP, and a plurality of sub-pixels 500 located between the driving back panel BP and the base substrate 1. FIG. 10B only shows one sub-pixel 500. Each of the sub-pixels 500 includes a sub-pixel light-emitting region 501 located inside the sub-pixel 500. As shown in FIG. 10A, the sub-pixels 500 included in the display panel 100 can be divided into a plurality of pixel islands P (for example, pixel island P1 and pixel island P2 shown in FIG. 10A), and one pixel island P1 can include m number of sub-pixels 500. The sub-pixels 500 in the same pixel island P1 display the same color. For example, the sub-pixel 500 includes a red sub-pixel (R), a green sub-pixel (G) and a blue sub-pixel (B), and the sub-pixels included in the same pixel island P1 are all red sub-pixels (R), or the sub-pixels included in the same pixel island P1 are all green sub-pixels (G), or the sub-pixels included in the same pixel island P1 are all blue sub-pixels (B). Here, one pixel island P may correspond to n number of micro lenses along a direction perpendicular to an extension direction of the micro lens 2 (i.e., X direction), m is greater than or equal to 2, and m is greater than or equal to n (e.g., n=1). Of course, the values of m and n can be set according to actual needs. It should be noted that, for pixel islands on the same display panel, the number of pixel islands at different positions may be different for the purpose of 3D display, and the number n of micro lenses corresponding to different pixel islands may also be different. For one pixel island, m is greater than or equal to n. It should be noted that one pixel island P can correspond to n number of micro lenses, which can be understood as an orthographic projection of each of the n micro lenses on the display panel 100 at least partially overlaps the light-emitting region 501 of at least one sub-pixel 500 in the pixel island P, and the orthographic projections of the two outermost micro lenses of n micro lenses (if n=1, the micro lenses itself) on the display panel 100 (if n=1, then the micro lenses itself) at least partially overlap the light-emitting region 501 of the outermost sub-pixel 500 in the pixel island P.

Specifically, by setting the corresponding relationship between the microlens structure and the pixel islands, the light emitted by each sub-pixel in the pixel islands is refracted by the microlens structure to disperse to different pixel areas, so that the human eyes can watch different images, thereby realizing 3D display effect.

As shown in FIG. 10B, the driving back panel BP includes a buffer layer 20, an active layer 30, a first gate insulating layer 40, a first gate layer 50, a second gate insulating layer 60, a second gate layer 70, an interlayer insulating layer 80, a first source-drain metal layer 90, a passivation layer 100, a first planarization layer 110, a second source-drain metal layer 120, and a second planarization layer 130, which are stacked on the base substrate 10 in sequence. Each sub-pixel includes an anode 140, a light-emitting layer 160, and a cathode 170 disposed on the second planarization layer 130. The display panel 100 further includes a pixel defining layer 150 defining sub-pixels and an encapsulation layer 180 between the cathode 170 and the interlayer 300. Here, the first source-drain metal layer 90 and the second source-drain metal layer 120 are electrically connected through a first via hole V1 penetrating the first planarization layer 110 and the passivation layer 100, and the anode 140 is electrically connected to the second source-drain metal layer 120 through a second via hole V2 penetrating the second planarization layer 130.

When the thermal reflow process is used to fabricate the micro lenses on the display panel, the alignment deviation between the microlens structure and the display panel can be less than or equal to 5 μm. In the related art, for example, when using nanoimprinting to make micro lenses, due to process limitations, the alignment deviation between the microlens structure and the display panel is greater than or equal to 10 μm. Further, when the micro lenses is fabricated on the display panel by the thermal reflow process, the angle deviation between the microlens structure and the display panel is less than or equal to 0.2°. Therefore, when the micro lenses manufactured by the thermal reflow process is used for 3D display, it can reduce the interference of the alignment deviation on the display effect, and can achieve a better light output effect.

In specific implementation, in the above-mentioned display apparatus provided by the embodiments of the present disclosure, the display panel 100 has a display area AA, and the edge of the display area AA is defined by the edge of the light-emitting area of the outermost sub-pixel. Here, the alignment deviation between the microlens structure and the display panel can be defined in the following manner: as shown in FIG. 10A, taking m=4, n=1 as an example, along a direction perpendicular to an extension direction of the micro lens 2 (i.e., X direction), a midpoint of a distance between the outermost side of the light-emitting region 501 of the outermost sub-pixel 500 in the pixel island P1 on the edge of the display area AA and the outermost side of the light-emitting region 501 of the outermost sub-pixel 500 in the pixel island P2 on the opposite side edge of the display area AA, is a first midpoint A1. A midpoint of a distance between the edge of the micro lenses 2 corresponding to the outermost sub-pixel 500 in P1 near the edge of the display area AA and the edge of the micro lenses 2 corresponding to the outermost sub-pixel 500 in P2 near the edge of the display area AA, is a second midpoint A2. A distance d between the first midpoint A1 and the second midpoint A2 along the direction perpendicular to the extension direction of the micro lens 2 is less than or equal to 5 μm. In this way, the angular deviation between the micro lenses 2 and the pixel island P1 can be made less than or equal to 0.2°, which meets the requirements of 3D display. In the practical test, when the micro lenses are manufactured by using the thermal reflow process, the angular deviation between the micro lenses 2 and the pixel island P1 can be even made less than or equal to 0.008°. Therefore, the microlens structure fabricated on the light-emitting side of the display panel 100 by using the thermal reflow process provided by the embodiments of the present disclosure can greatly improve the alignment accuracy between the micro lenses and the pixel island, reduce processing costs, and realize the direct integration of the microlens structure into the display panel with processing methods in the factory.

It can be understood that the above specific embodiments provide a form of alignment deviation measurement of a microlens structure and a display panel. According to the differences in the form and combination form of the display panel and the microlens structure, a corresponding measurement method can be given. Generally, the midpoint of the distance between the edges of the light-emitting region corresponding to the sub-pixel closest to the edge of the display area AA can be measured, and the midpoint of the distance between the edges of the micro lenses corresponding to the sub-pixel closest to the edge of the display area AA can be measured. The alignment deviation is obtained by calculating the horizontal distance between the midpoints along a direction in which the micro lenses are arranged (for example, in the above embodiments, perpendicular to the extension direction of a micro lens).

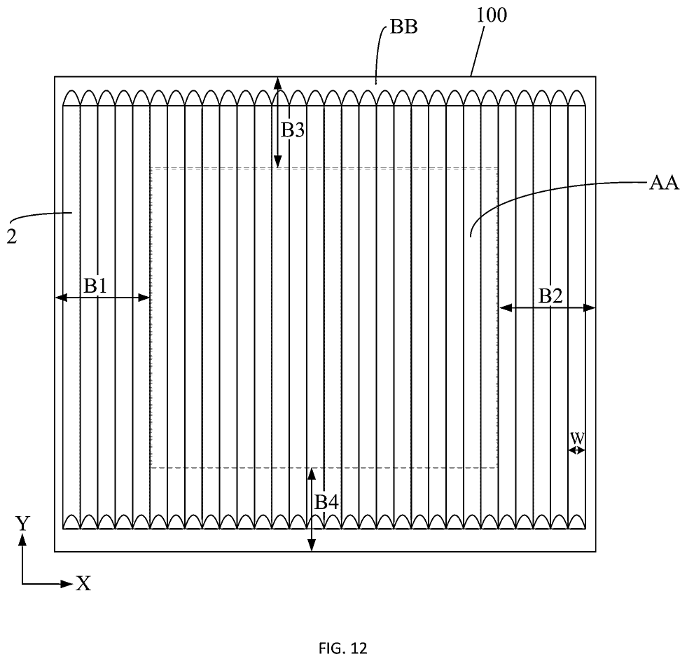

In specific implementation, in the above-mentioned display apparatus provided by the embodiments of the present disclosure, as shown in FIG. 12, the display panel 100 has a display area AA and a peripheral area BB arranged around the display area AA. The display area AA is provided with a plurality of pixel islands P as shown in FIG. 10A. The peripheral area BB includes: a first sub-area B1 and a second sub-area B2 along a direction perpendicular to the extension direction of a micro lens 2 (i.e. X direction), and a third sub-area B3 and a fourth sub-area B4 along the extension direction of a micro lens (i.e. Y direction).

Along the direction perpendicular to the extension direction of the micro lens 2, the number of micro lenses 2 arranged in the first sub-area B1 and the second sub-area B2 is greater than or equal to 5. In order to avoid the non-display area being too wide, preferably, 5-10 micro lenses 2 are arranged. 5 micro lenses are taken as an example in FIG. 12.

Preferably, along the direction perpendicular to the extension direction of the micro lens 2 (i.e. X direction), a width of a micro lens 2 is a first width W1, a distance between micro lenses 2 is a second width W2. The length of the micro lenses 2 extending to the third sub-area B3 and the fourth sub-area B4 are k times (W1+W2), or kW1+(k−1)W2, where k is greater than or equal to 5. In this way, light crosstalk at the edge of the display area AA can be avoided, and the display effect can be improved. Preferably, B1=B2, B3=B4. Further preferably, B1=B2=B3=B4.

The microlens structure, the manufacturing method therefor, and the display apparatus provided by the embodiments of the present disclosure can greatly improve the transmittance of the micro lenses by using non-photosensitive resin to form the microlens structure through thermal initiation, and avoid a problem of yellowing of the micro lenses made of photosensitive resin in the related art.

While preferred embodiments of the present disclosure have been described, additional changes and modifications can be made to these embodiments by those skilled in the art once the basic inventive concept is appreciated. Therefore, it is intended that the appended claims be construed to cover the preferred embodiment and all changes and modifications which fall within the scope of the present disclosure.

It should be noted that, the range expressions such as “m1-m2” appearing in the specification include endpoint values of m1 and m2.

Apparently, those skilled in the art can make various changes and modifications to the embodiments of the present disclosure without departing from the spirit and scope of the embodiments of the present disclosure. In this way, if these modifications and variations of the embodiments of the present disclosure fall within the scope of the claims of the present disclosure and their equivalent technologies, the present disclosure also intends to include these modifications and variations.

1. A microlens structure, comprising:
a base substrate;
a plurality of micro lenses located on one side of the base substrate; wherein a material of the micro lenses comprises a product of cross-linked non-photosensitive resin monomer.

2. The microlens structure according to claim 1, wherein in 400 nm-600 nm band, a transmittance of non-photosensitive resin is greater than or equal to 50%.

3. The microlens structure according to claim 1, wherein the material of the micro lenses does not comprise a photosensitive group.

4. The microlens structure according to claim 1, wherein the product of cross-linked non-photosensitive resin monomer comprises at least one of polyacrylic resin, polyimide resin or phenolic resin.

5. The microlens structure according to claim 1, wherein a surface figure accuracy of the micro lenses is less than 10 nm, and a roughness of the micro lenses is less than 1 nm.

6. The microlens structure according to claim 1, further comprising a light-shielding layer between the base substrate and the micro lenses, wherein the light-shielding layer comprises a plurality of sub-shielding parts arranged at intervals, and each of the sub-shielding parts is located in a gap between adjacent micro lenses.

7. The microlens structure according to claim 6, wherein the micro lenses cover edges of the sub-shielding parts.

8. A display apparatus, comprising: a display panel, and a microlens structure located on a light-emitting side of the display panel, wherein the microlens structure comprises:
a base substrate;
a plurality of micro lenses located on one side of the base substrate; wherein a material of the micro lenses comprises a product of cross-linked non-photosensitive resin monomer.

9. The display apparatus according to claim 8, wherein the base substrate of the microlens structure is an interlayer, and the display apparatus further comprises a planarization layer on a side of the micro lenses away from the base substrate, and a refractive index of the planarization layer is smaller than a refractive index of the micro lenses.

10. The display apparatus according to claim 8, wherein an alignment deviation between the microlens structure and the display panel is less than or equal to 5 μm.

11. The display apparatus according to claim 8, wherein the display panel comprises: a driving back panel, and a plurality of sub-pixels between the driving back panel and the base substrate; the plurality of sub-pixels are divided into a plurality of pixel islands, each of the pixel islands comprises a plurality of sub-pixels, and sub-pixels in a same pixel island display a same color; wherein
along a direction perpendicular to an extension direction of one of the micro lenses, one of the pixel islands corresponds to at least one of the micro lenses, and a quantity of sub-pixels comprised in each of the pixel islands is greater than or equal to a quantity of the micro lenses corresponding to the each of the pixel islands.

12. The display apparatus according to claim 10, wherein the display panel comprises a display area and a peripheral area disposed around the display area, the peripheral area comprises: a first sub-area and a second sub-area along a direction perpendicular to an extension direction of one of the micro lenses, and a third sub-area and a fourth sub-area along the extension direction of one of the micro lenses; wherein along the extension direction perpendicular to one of the micro lenses, a quantity of the micro lenses arranged in the first sub-area and the second sub-area is greater than or equal to 5, respectively.

13. A method for manufacturing the microlens structure according to claim 1, comprising:
fabricating the plurality of micro lenses on the base substrate; wherein a material of the micro lenses is a product of cross-linked non-photosensitive resin.

14. The method according to claim 13, wherein the fabricating the plurality of micro lenses on the base substrate, comprises:
forming a non-photosensitive resin layer on the base substrate;
coating a photoresist layer on a side of the non-photosensitive resin layer away from the base substrate;
exposing and developing the photoresist layer to form a photoresist pattern;
etching the non-photosensitive resin layer by using the photoresist pattern as a mask, to form a non-photosensitive resin pattern;
removing the photoresist pattern; and
performing a thermal reflow process on the non-photosensitive resin pattern to form the plurality of micro lenses.

15. The method according to claim 14, wherein after the forming the non-photosensitive resin layer on the base substrate, and before the coating the photoresist layer on the side of the non-photosensitive resin layer away from the base substrate, the method further comprises:
forming a passivation layer on a side of the non-photosensitive resin layer away from the base substrate.

16. The method according to claim 15, wherein after the forming the photoresist pattern and before the etching the non-photosensitive resin layer by using the photoresist pattern as a mask, the method further comprises:
etching the passivation layer by using the photoresist pattern as a mask, to form a passivation layer pattern.

17. The method according to claim 16, wherein the etching the non-photosensitive resin layer by using the photoresist pattern as a mask, to form the non-photosensitive resin pattern, comprises:
etching the non-photosensitive resin layer by using the photoresist pattern and the passivation layer pattern as a mask, to form the non-photosensitive resin pattern.

18. The method according to claim 13, wherein before the fabricating the plurality of micro lenses on the base substrate, the method further comprises:
forming a light-shielding layer on the base substrate; wherein the light-shielding layer comprises a plurality of sub-shielding parts arranged at intervals, and each of the sub-shielding parts is located in a gap between adjacent micro lenses.

19. The method according to claim 17, wherein after forming the non-photosensitive resin pattern and before performing the thermal reflow process on the non-photosensitive resin pattern, the method further comprises:
removing the passivation layer pattern while removing the photoresist pattern.
